(19) United States
(12) Patent Application Publication
(10) Pub. No.: US 2025/0103783 A1
(43) Pub. Date: Mar. 27, 2025

(54) CO-SIMULATION ON A SYSTEM-ON-CHIP

(71) Applicant: Xilinx, Inc., San Jose, CA (US)

(72) Inventors: Alok Mistry, Hyderabad (IN); Anil Kumar A V, Hyderabad (IN)

(73) Assignee: Xilinx, Inc., San Jose, CA (US)

(21) Appl. No.: 18/371,937

(22) Filed: Sep. 22, 2023

(51) Int. Cl. G06F 30/3308

(52) U.S. Cl. CPC G06F 30/3308

(57) ABSTRACT

A system-on-chip (SoC) has programmable logic and a processor. A design tool generates configuration data to implement circuitry for emulation of a design-under-test (DUT) on the programmable logic and generates testbench executable code. The testbench executable code is configured to generate stimuli to the circuitry on the programmable logic. The processor can be configured to execute the testbench executable code and the programmable logic can be configured to implement the circuitry for emulation of the DUT.

### TECHNICAL FIELD

The disclosure generally relates to co-simulation of circuit designs.

### BACKGROUND

Simulating a circuit design may involve separating the design into parts that are simulated on different simulation platforms. A co-simulation can run a testbench program on a computer system (a “software platform”), such as a desktop, server or other type of computer system and emulate parts of the circuit design (design-under-test or “DUT”) on a hardware platform, such as a platform having one or more programmable logic devices.

Emulating part of the design on a hardware co-simulation platform reduces simulation time relative to simulating the design on a computer system. However, existing approaches to partitioning a design for co-simulation are inefficient, which is a result of the overhead involved in exchanging data between the hardware and software platforms during co-simulation.

### SUMMARY

A disclosed method includes generating configuration data by a design tool to implement circuitry for emulation of a design-under-test (DUT) on programmable logic of a system-on-chip (SoC). The method includes generating testbench executable code from testbench source code by the design tool. The testbench executable code is configured to generate stimuli to the circuitry on the programmable logic. The method includes configuring a processor of the SoC to execute the testbench executable code and the programmable logic to implement the circuitry for emulation of the DUT.

A disclosed system includes one or more computer processors configured to execute program code and a memory arrangement coupled to the one or more computer processors. The memory arrangement is configured with instructions of a design tool that when executed by the one or more computer processors cause the one or more computer processors to perform operations that include generating configuration data to implement circuitry for emulation of a design-under-test (DUT) on programmable logic of a system-on-chip (SoC). The operations include generating testbench executable code, and the testbench executable code is configured to generate stimuli to the circuitry on the programmable logic. The operations include configuring a processor of the SoC to execute the testbench executable code and the programmable logic to implement the circuitry for emulation of the DUT.

A disclosed system-on-chip (SoC) includes programmable logic circuitry configured to emulate a design-under-test (DUT) and a processor coupled to the programmable logic circuitry. The processor is configured to execute testbench executable code that generates stimuli to the DUT.

Other features will be recognized from consideration of the Detailed Description and Claims, which follow.

### BRIEF DESCRIPTION OF THE DRAWINGS

Various aspects and features of the method and system will become apparent upon review of the following detailed description and upon reference to the drawings in which:

FIG. 1 shows an exemplary compilation flow and configuration of an SoC for co-simulation;

FIG. 2 shows an SoC having a processing subsystem configured to execute testbench code and instrumentation code, and having a programmable logic subsystem configured to emulate a DUT or a portion thereof;

FIG. 3 shows the software stack in a use case involving bare metal testbench executable code;

FIG. 4 shows the software stack in a use case in which the testbench executable code relies on support from an operating system;

FIG. 5 shows the software stack in a use case in which the testbench source code has SystemC code;

FIG. 6 shows the software stack in a use case in which the testbench is specified as HDL code, and an HDL simulator executes on top of an OS;

FIG. 7 shows the software stack in a use case in which the testbench is specified as SystemVerilog source consistent with a universal verification methodology (“UVM”) or an open verification methodology (“OVM”);

FIG. 8 is a block diagram illustrating an exemplary data processing system; and

FIG. 9 is a block diagram depicting a System-on-Chip (SoC) that can host the executable testbench, instrumentation code, instrumentation circuitry and DUT according to an example.

### DETAILED DESCRIPTION

In the following description, numerous specific details are set forth to describe specific examples presented herein. It should be apparent, however, to one skilled in the art, that one or more other examples and/or variations of these examples, all of which are non-limiting, may be practiced without all the specific details given below. In other instances, well known features have not been described in detail so as not to obscure the description of the examples herein. For ease of illustration, the same reference numerals may be used in different diagrams to refer to the same elements or additional instances of the same element.

The disclosed methods and systems reduce co-simulation time by reducing the overhead involved in exchange of data between the testbench code and the emulated circuit. The disclosed methods and systems generate executable program code for a testbench and configuration data for emulating a circuit design. The methods and systems configure an SoC, which has a processor and programmable logic, to execute the testbench code and emulate the circuit design (or a portion thereof). The overhead is reduced by the exchange of data being between SoC circuitry rather than through input/output (“I/O”) channels that span between hardware and software platforms. The term, “software domain,” may be used to refer to C/C++/SystemC and/or behavioral hardware description language (“HDL”) testbench code constructed to provide stimulus to the DUT and to execute on a computer processor. The term, “hardware domain,” may be used to refer to register transfer level (“RTL”) code that specifies the DUT and can be synthesized for emulation on logic gates of programmable logic circuitry.

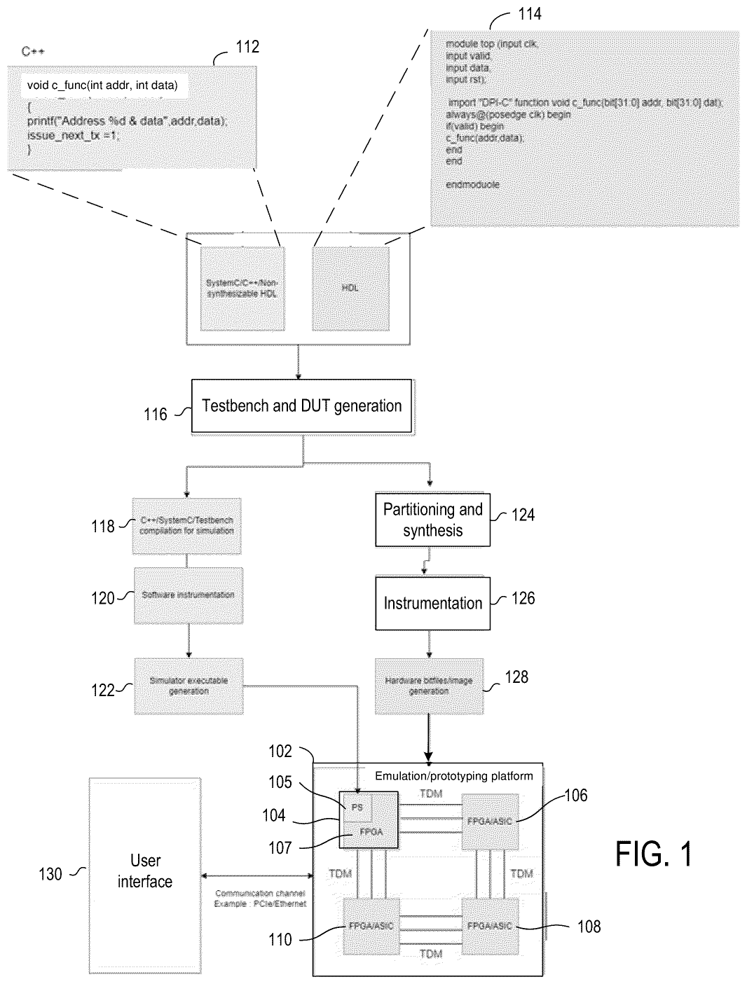

FIG. 1 shows an exemplary compilation flow and configuration of an SoC for co-simulation. The emulation/prototyping platform 102 includes at least one SoC 104 and can include one or more additional devices to provide emulation/prototyping for scenarios in which a single device lacks the resources to emulate/prototype the DUT.

The exemplary emulation/prototyping platform includes three devices 106, 108, and 110 in addition to the SoC 104. The additional devices on the emulation/prototyping platform can be field programmable gate array (“FPGA”) devices, application specific integrated circuits (ASICs) devices, or additional SoCs. For emulation some vendors provide ASICs in the form of multiple custom processors communicatively coupled in a grid. The RTL code is compiled for emulation of gate-level behavior by the processors executing the compiled code. The ASICs are tailored to emulate the circuit specified by the RTL and provide features of probing signals and/or capturing waveforms etc. Other vendors provide FPGA devices that can be configured to emulate the gate-level behavior based on an RTL design. For prototyping, FPGA devices are generally preferred.

The SoC 104 includes a processing subsystem (“PS”) 105, which can include multiple processors, and a programmable logic subsystem that includes FPGA circuitry 107. The processing subsystem supports a co-simulation that can execute various testbench configurations that range from bare metal code compiled from C/C++ source code to a testbench reliant on an operating system (e.g., Linux) executing on the processor(s).

A workstation can provide a user interface 130 for configuring and/or interacting with the emulation/prototyping platform at runtime.

FIG. 1 shows an example of a portion of the source code 112 of a testbench and a portion of the RTL code 114 of a DUT. The testbench source code is targeted for execution on a processor or multiple processors of the SoC 104, and can be C/C++, SystemC, or non-synthesizable behavioral HDL code, for example. The exemplary RTL code 114 of the DUT uses Direct Programming Interface (“DPI”) to invoke “c_func” in the software domain with set of arguments in response to satisfaction of a given condition. The RTL code specifies, testing the state of a “valid” signal at each clock edge and conditionally calling “c_func.”

The testbench source code 112 and DUT source code 114 can be input to a design tool for generating the testbench executable code and configuration data for DUT emulation as shown by block 116. The design tool compiles the testbench source code for a processor(s) of the SoC as shown by block 118. At block 120, Instrumentation code is added to the testbench executable code by the design tool to provide an interface between the testbench code and the emulation circuitry.

The design tool generates testbench executable code at block 122. If the SoC has multiple processors, the design tool can partition the testbench source code into multiple partitions and compile the partitions for execution on the processors. For example, testbench source code having functions c_test1( ), c_test2( ), c_test3( ), . . . , can be partitioned and compiled such that the executable code of c_test1( ) will be executed on one processor, the executable code of c_test2( ) will be executed on another processor, the executable code of c_test3( ) will be executed on yet another processor etc. The design tool will also generate separate instrumentation code for each of the processors. The partitioning of the testbench enables testbench functions to execute in parallel execution of testbench function, in addition to running in parallel with the DUT.

At block 124, the design tool can partition the DUT and synthesize the design into a netlist. For a large design that cannot be emulated on a single device, the design tool can partition the design for emulation across multiple devices. The design tool can generate time division multiplexing (“TDM”) logic at various I/O boundaries as known in the art.

In addition to partitioning, the design tool generates instrumentation logic at block 126. The instrumentation logic is added to the nettlist to implement an instrumentation interface to communicate with the testbench executable code.

Based on the instrumented netlist, at block 128 the design tool generates configuration data to implement circuitry to emulate the DUT on the emulation device(s). Depending on the type of device, the generation of the image can include place-and-route along with bitstream generation for FPGA circuitry, or generation of executable code for ASIC devices.

To configure the emulation/prototyping platform for co-simulation, the design tool configures a processor(s) of the SoC 104 to execute the testbench executable code, including the instrumentation code, and configures one or more of the devices 106, 108, and 110 to implement circuitry of the instrumentation interface and circuitry to emulate the DUT.

The design tool can provide a user interface 130 for configuration of the platform 102. By invocation of functions of the design tool, a user can instantiate testbench executable code on the SoC for execution by a processor and configure programmable logic of the SoC. In addition, the user can commence the co-simulation and optionally view runtime behavior. The design tool can be communicatively coupled to the emulation/prototyping platform via PCie or Ethernet bus.

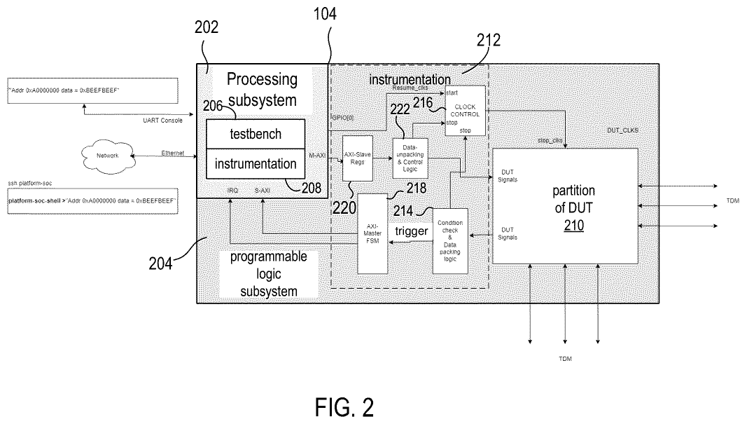

FIG. 2 shows an SoC 104 having a processing subsystem 202 configured to execute testbench code 206 and instrumentation code 208, and having a programmable logic subsystem 204 configured to emulate a DUT or a portion 210 thereof. An SoC can be structured as a single semiconductor die having a processing subsystem and a programmable logic subsystem disposed thereon. Alternatively, an SoC can be structured as a processing subsystem and a programmable logic subsystem disposed on multiple semiconductor dice that are interconnected by a silicon interposer(s). The programmable logic subsystem includes FPGA circuitry, for example. The FPGA circuitry of the programmable logic subsystem is configured with DUT instrumentation interface 212.

In an exemplary SoC, the processing subsystem can be communicatively coupled to the programmable logic subsystem by an Advanced extensible Interface (“AXI”) bus. The testbench instrumentation code 208 and instrumentation interface 212 support communication between the testbench executable code and the DUT circuitry 210.

During co-simulation runtime, the condition check logic 214 of the instrumentation interface monitors DUT signals to determine when a test condition(s), which was specified in the DUT source code, has been satisfied. In the example code 114 of FIG. 1, the condition is: posedge of clk & valid. In response to the signal(s) satisfying the condition, the condition check logic issues a stop-clock signal to the clock control block logic 216, and issues a trigger signal to an AXI Master finite state machine (“FSM”) 218 of the instrumentation interface. In response to the stop-clock signal, the clock control logic 216 of the instrumentation interface asserts a stop-clks signal to the DUT logic to stop oscillation of the clock signal(s) that drive the DUT.

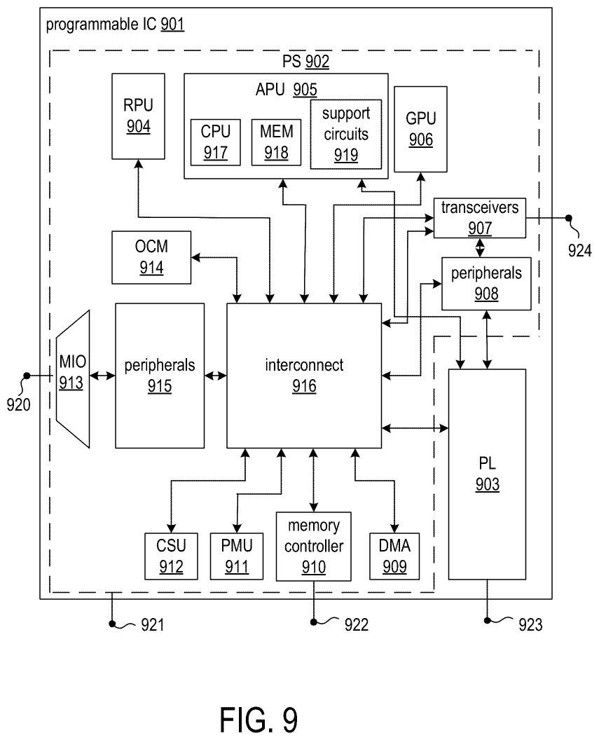

In combination with logic for condition checking, logic 214 includes data packing logic. In response to satisfaction of the condition, the data packing logic combines signal values in registers (not shown). The signal values are those specified in the DUT source code, which in the example are “addr” and “data” specified as arguments to the c_func function call. The AXI Master FSM writes data from the registers to allocated addresses in memory (not shown; see FIG. 9) shared with the processing subsystem. In addition, the AXI Master FSM issues an interrupt signal to the processing subsystem. In this context, the processing subsystem functions as the AXI slave to the AXI Master FSM.

In response to receiving the interrupt, the processing subsystem reads the vector address associated with the interrupt and redirects execution (jumps) to the (instrumented/modified) function, c_func. In executing c_func, the data is output, such as displaying the data on a universal asynchronous receiver-transmitter (“UART”) console or output via an operating system (e.g., Linux). To input stimuli to the DUT 210, the testbench executable code 206 writes data to AXI slave registers 220 via the instrumentation code 208. In response to data written to the AXI slave registers, the data unpacking and control logic 222 issues a stop-clk signal to the clock control logic 216, which issues a stop-clks signal to the DUT 210. The data unpacking logic unpacks the data from the register(s) and generates signals on associated signals lines for input to the DUT 210.

Upon completing execution of the function, the processing subsystem issues a resume-clks signal to a general purpose I/O pin, which is connected to the clock control logic 216. In response, the clock control logic deasserts the stop-clks signal to the DUT, which enables oscillation of the clock signal(s) to drive the DUT.

Examples 1, 2, and 3 that follow show RTL code, testbench source code, and instrumentation source code generated based on the RTL and testbench source code. The instrumentation code invokes the testbench code by interacting with circuitry of the emulated DUT specified by the RTL code.

Example 1 shows a module in Verilog that defines a circuit to be emulated by an SoC. The “always” block calls “c_test” after every valid transaction (when posedge of “clk” and “valid” signal asserted to 1) and gets the next address to be issued from “c_func” and puts the address in register “next_addr.”

```
module top (input clk,
input rst);
reg [31:0] next_addr;
import “DPI-C” function int c_test(bit[31:0] addr, bit[31:0] wdata);
always@(posedge clk) begin
  if(rst) begin
    next_addr<=0;
  else if(valid) begin
    next_addr <= c_func(addr,wdata);
  end else begin
    next_addr <= next_addr;|
  end
end
always@(posedge clk) begin
  if(rst) begin
    addr<=0;
    wdata<=0;
    valid<=0;
  end else if(~valid) begin
    addr<=next_addr;
    wdata<=wdata+4;
    valid<=1;
  end else begin
    addr<=addr;
    wdata<=wdata;
    valid<=0;
  end
end
endmodule
```

### Example 1

Example 2 shows the source code of the function “c_test.” The function prints the address and data output by module “top,” and generates a new address that is returned as input to “top.”

```
int c_test(int addr, int wdata) {
  printf(“Address %d & data”, addr, wdata);
  addr = addr + random( );
  return addr;
}|
```

### Example 2

The source code in Example 3 shows the instrumentation code generated by the design tool based compilation of the RTL code and testbench source code of Examples 1 and 2. The instrumentation code includes “main” and “irq0_isr” functions.

The RTL specification of “import “DPI-C” function void c_test(bit[31:0] addr, bit[31:0] wdata)” provides information to design tool about the name of function to be invoked from “irq0_isr” and the arguments to be passed. The address at which arguments (addr & wdata) are stored by AXI Master FSM 218 and eventually read by “irq0_isr” can be determined based on reserved address space allocated in the on-chip memory (e.g., FIG. 9) of the SoC. For example, address 0x0000_1XXXX is reserved for DUT signals to be stored for software.

The function “irq0_isr” is the interrupt service routine, and “irq0” denotes the IRQ-0 pin connected to the processing subsystem 202 by the AXI master FSM to trigger c_test by checking condition of DUT signals in the DUT instrumentation circuitry 212. Upon power on, “irq0_isr” is registered/initialized upon execution of “main” as an interrupt service routine for irq0 pin.

Upon issue of IRQ-0 by the DUT instrumentation circuitry 212, “irq0_isr” is invoked, and “irq0_isr” reads the arguments written by the DUT instrumentation circuitry into the specified memory addresses. Upon reading, “irq0_isr” will invoke “c_test”. Upon completion of execution of “c_test,” the return value is stored in the specified address for “next_addr” signal in the DUT instrumentation circuitry (AXI-Slave register 220. For example, address 0x8000_0XXXX is reserved for the software instrumentation 208 to store the return value for hardware DUT signals. Upon completion, “irq0_isr” triggers the hardware clock control logic 216 to resume clock signals to the DUT 210.

```
void irq0_isr( ) {
  // read “addr” stored at 0x0000_1000
  int addr = read(0x00001000);
  // read “wdata” stored at 0x0000_1004
  int wdata = read(0x00001004);
  // calling c_test
  int next_addr = c_test(addr,wdata);
  // write “next_addr” to hardware instrumentation
  write(0x80000000,next_addr);
  // Resume hardware clocks
  start_clock( );
}
void main( ) {
  // registering irq pint 0 to irq0_isr function
  register_irq(0, irq0_isr);
  while(1);
}
```

### Example 3

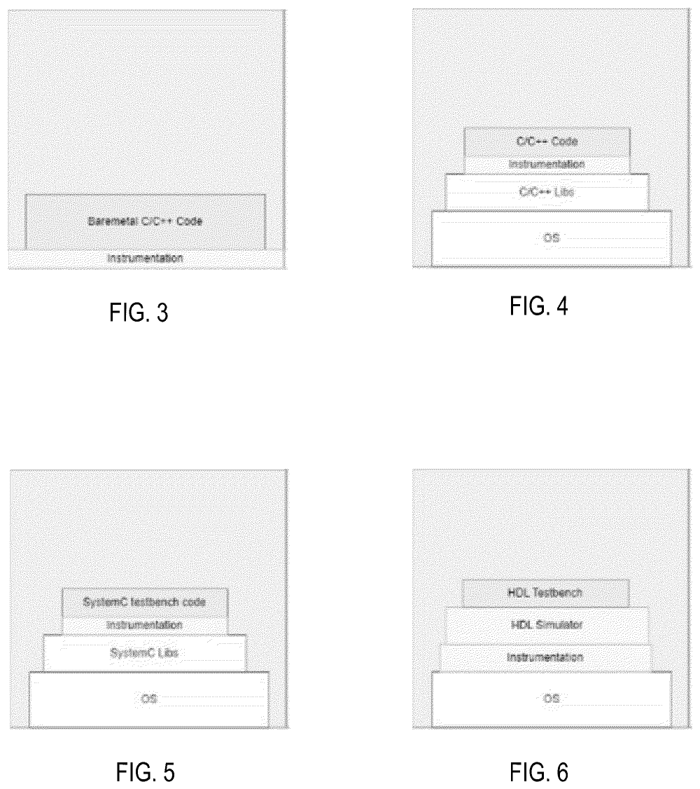

FIGS. 3-7 show examples of how the instrumentation code 208 can be deployed in different software stacks executing on the processor of the SoC consistent with different use cases.

FIG. 3 shows the software stack in a use case involving bare metal testbench executable code. Bare metal code is program code that does not require an operating system for execution on the target hardware. The generated instrumentation code communicates directly with circuitry the instrumentation interface of the DUT.

FIG. 4 shows the software stack in a use case in which the testbench executable code relies on support from an operating system “OS,” such as Linux. In generating the instrumentation code, the design tool generates code that interfaces with the operating system. The SoC can be configured to boot the OS on a processor at emulation runtime.

An OS image can be booted on the processor and through the instrumentation code, the testbench code can be executed with support from libraries (e.g., C/C++ libraries) and the OS. This software stack covers use cases relying on system calls, such as “AVIPs” (accelerated verification intellectual properties from CADENCE®) in which the software portion of AVIP is executing on a processor and a hardware portion of AVIP is implemented on an FPGA.

FIG. 5 shows the software stack in a use case in which the testbench source code has SystemC code. The testbench source code can be ported to execute on top of the OS SystemC Libs. The instrumentation code can tunnel function calls to and from the DUT. This software stack covers use-cases in which the testbench relies on SystemC execution for cycle-accurate SoC models in SystemC, such as mixed signal models interacting with the DUT.

In generating the instrumentation code, the design tool generates code that provides an interface to SystemC library functions for communicating the stimuli to the instrumentation interface circuitry through the operating system. The SoC can be configured to boot the OS on a processor at emulation runtime.

FIG. 6 shows the software stack in a use case in which the testbench is specified as HDL code, and an HDL simulator executes on top of an OS. In generating the instrumentation code, the design tool generates code that interfaces between the HDL simulator and the operating system. The SoC can be configured to boot the OS on a processor and execute the HDL simulator at emulation runtime.

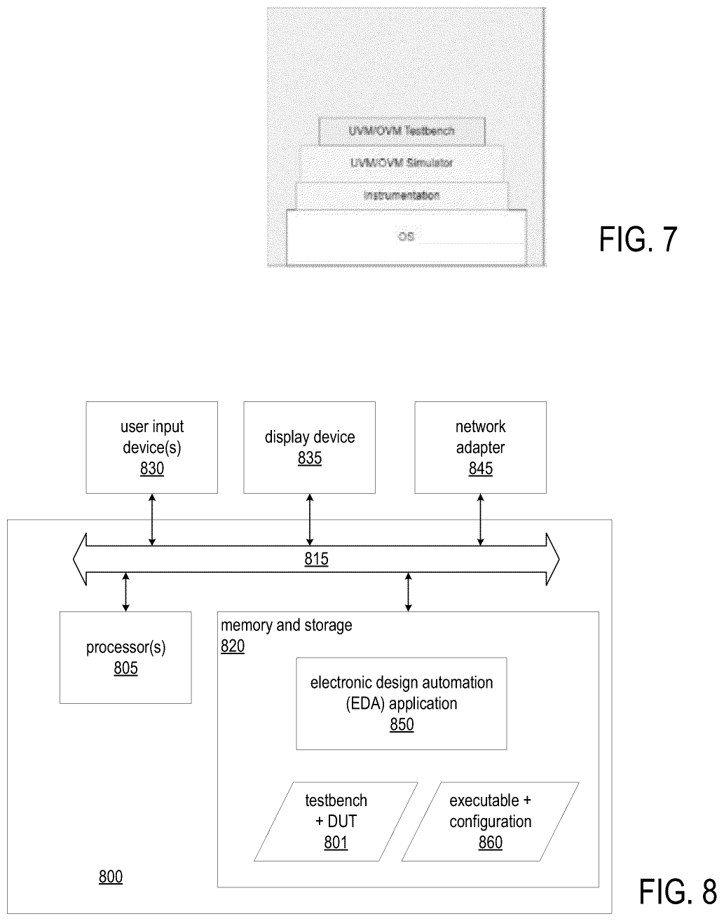

FIG. 7 shows the software stack in a use case in which the testbench is specified as SystemVerilog source consistent with a universal verification methodology (“UVM”) or an open verification methodology (“OVM”). UVM and OVM are standardized methodologies for verifying integrated circuit designs. A UVM/OVM simulator executes on top of the OS. In generating the instrumentation code, the design tool generates code that interfaces between the UVM/OVM simulator and the operating system. The SoC can be configured to boot the OS on a processor and execute the UVM/OVM simulator at emulation runtime.

FIG. 8 is a block diagram illustrating an exemplary data processing system (system) 800. System 800, which is configured as a design tool, is an example of an electronic design automation (“EDA”) system. As pictured, system 800 includes at least one processor circuit (or “processor”), e.g., a central processing unit (CPU) 805 coupled to memory and storage arrangement 820 through a system bus 815 or other suitable circuitry. System 800 stores program code and input code 801 within memory and storage arrangement 820. Processor 805 executes the program code accessed from the memory and storage arrangement 820 via system bus 815. In one aspect, system 800 is implemented as a computer or other data processing system that is suitable for storing and/or executing program code. It should be appreciated, however, that system 800 can be implemented in the form of any system including a processor and memory that is capable of performing the functions described within this disclosure.

Memory and storage arrangement 820 includes one or more physical memory devices such as, for example, a local memory (not shown) and a persistent storage device (not shown). Local memory refers to random access memory or other non-persistent memory device(s) generally used during actual execution of the program code. Persistent storage can be implemented as a hard disk drive (HDD), a solid state drive (SSD), or other persistent data storage device. System 800 may also include one or more cache memories (not shown) that provide temporary storage of at least some program code and data in order to reduce the number of times program code and data must be retrieved from local memory and persistent storage during execution.

Input/output (I/O) devices such as user input device(s) 830 and a display device 835 may be optionally coupled to system 800. The I/O devices may be coupled to system 800 either directly or through intervening I/O controllers. A network adapter 845 also can be coupled to system 800 in order to couple system 800 to other systems, computer systems, remote printers, and/or remote storage devices through intervening private or public networks. Modems, cable modems, Ethernet cards, and wireless transceivers are examples of different types of network adapter 845 that can be used with system 800.

Memory and storage arrangement 820 may store an EDA application 850. EDA application 850, being implemented in the form of executable program code, is executed by processor(s) 805. As such, EDA application 850 is considered part of system 800. System 800 while executing EDA application 850, receives and operates on input code 801. Input code 801 includes the testbench source code and DUT specification. In one aspect, system 800 compiles the testbench code and performs a design flow on the DUT code. The design flow can include synthesis, mapping, placement, routing, and generating configuration data for programmable logic. System 800 generates an executable testbench, instrumentation code and configuration data as output code 860.

EDA application 850, input code 801, output code 860, and any data items used, generated, and/or operated upon by EDA application 850 are functional data structures that impart functionality when employed as part of system 800 or when such elements, including derivations and/or modifications thereof, are loaded into an IC such as a programmable IC causing implementation and/or configuration of a circuit design within the programmable IC.

FIG. 9 is a block diagram depicting a System-on-Chip (SoC) 901 that can host the executable testbench, instrumentation code, instrumentation circuitry and DUT according to an example. In the example, the SoC includes the processing subsystem (PS) 902 and the programmable logic subsystem 903. The processing subsystem 902 includes various processing units, such as a real-time processing unit (RPU) 904, an application processing unit (APU) 905, a graphics processing unit (GPU) 906, a configuration and security unit (CSU) 912, and a platform management unit (PMU) 911. The PS 902 also includes various support circuits, such as on-chip memory (OCM) 914, transceivers 907, peripherals 908, interconnect 916, DMA circuit 909, memory controller 910, peripherals 915, and multiplexed (MIO) circuit 913. The processing units and the support circuits are interconnected by the interconnect 916. The PL subsystem 903 is also coupled to the interconnect 916. The transceivers 907 are coupled to external pins 924. The PL 903 is coupled to external pins 923. The memory controller 910 is coupled to external pins 922. The MIO 913 is coupled to external pins 920. The PS 902 is generally coupled to external pins 921. The APU 905 can include a CPU 917, memory 918, and support circuits 919. The APU 905 can include other circuitry, including L1 and L2 caches and the like. The RPU 904 can include additional circuitry, such as L1 caches and the like. The interconnect 916 can include cache-coherent interconnect or the like.

Referring to the PS 902, each of the processing units includes one or more central processing units (CPUs) and associated circuits, such as memories, interrupt controllers, direct memory access (DMA) controllers, memory management units (MMUs), floating point units (FPUs), and the like. The interconnect 916 includes various switches, busses, communication links, and the like configured to interconnect the processing units, as well as interconnect the other components in the PS 902 to the processing units.

The OCM 914 includes one or more RAM modules, which can be distributed throughout the PS 902. For example, the OCM 914 can include battery backed RAM (BBRAM), tightly coupled memory (TCM), and the like. The memory controller 910 can include a DRAM interface for accessing external DRAM. The peripherals 908, 915 can include one or more components that provide an interface to the PS 902. For example, the peripherals can include a graphics processing unit (GPU), a display interface (e.g., DisplayPort, high-definition multimedia interface (HDMI) port, etc.), universal serial bus (USB) ports, Ethernet ports, universal asynchronous transceiver (UART) ports, serial peripheral interface (SPI) ports, general purpose (GPIO) ports, serial advanced technology attachment (SATA) ports, PCIe ports, and the like. The peripherals 915 can be coupled to the MIO 913. The peripherals 908 can be coupled to the transceivers 907. The transceivers 907 can include serializer/deserializer (SERDES) circuits, MGTs, and the like.

Various logic may be implemented as circuitry to carry out one or more of the operations and activities described herein and/or shown in the figures. In these contexts, a circuit or circuitry may be referred to using terms such as “logic,” “module,” “engine,” “generator,” or “block.” It should be understood that elements labeled by these terms are all circuits that carry out one or more of the operations/activities. In certain implementations, a programmable circuit is one or more computer circuits programmed to execute a set (or sets) of instructions stored in a ROM or RAM and/or operate according to configuration data stored in a configuration memory.

Though aspects and features may in some cases be described in individual figures, it will be appreciated that features from one figure can be combined with features of another figure even though the combination is not explicitly shown or explicitly described as a combination.

The methods and system are thought to be applicable to a variety of systems for co-simulation. Other aspects and features will be apparent to those skilled in the art from consideration of the specification. It is intended that the specification and drawings be considered as examples only, with a true scope of the invention being indicated by the following claims.

What is claimed is:

1. A method comprising:
generating configuration data by a design tool to implement circuitry for emulation of a design-under-test (DUT) on programmable logic of a system-on-chip (SoC);
generating testbench executable code from testbench source code by the design tool, wherein the testbench executable code is configured to generate stimuli to the circuitry on the programmable logic; and
configuring a processor of the SoC to execute the testbench executable code and the programmable logic to implement the circuitry for emulation of the DUT.

2. The method of claim 1, further comprising:
generating instrumentation code to execute on the processor;
generating configuration data to implement an instrumentation interface as circuitry on the programmable logic; and
configuring the processor to execute the instrumentation code and the programmable logic to implement the instrumentation interface.

3. The method of claim 2, wherein generating the instrumentation code includes generating instrumentation code that communicates directly with the circuitry of the instrumentation interface.

4. The method of claim 2, wherein:
generating the instrumentation code includes generating instrumentation code that interfaces with an operating system; and
configuring the processor includes configuring the SoC to boot the operating system on the processor.

5. The method of claim 2, wherein:
the testbench source code includes SystemC code;
generating the instrumentation code includes generating instrumentation code that provides an interface to SystemC library functions for communicating the stimuli to the instrumentation interface through an operating system; and
configuring the processor includes configuring the SoC to boot the operating system on the processor and execute the SystemC library functions.

6. The method of claim 2, wherein:
the testbench source code includes hardware description language (HDL) code;
generating the testbench executable code includes generating code that interfaces with an HDL simulator;
generating the instrumentation code includes generating code that interfaces between the HDL simulator and an operating system; and
configuring the processor includes configuring the SoC to boot the operating system on the processor and execute the HDL simulator.

7. The method of claim 2, wherein:
the testbench source code is structured according to a universal verification methodology (UVM) or an open verification methodology (OVM);
generating the testbench executable code includes generating code that interfaces with a UVM or OVM simulator;
generating the instrumentation code includes generating code that interfaces between the UVM or OVM simulator and an operating system; and
configuring the processor includes configuring the SoC to boot the operating system on the processor and execute the UVM or OVM simulator.

8. The method of claim 1, further comprising:
generating instrumentation code to execute on the processor;
generating configuration data to implement an instrumentation interface as circuitry on the programmable logic;
configuring the processor to execute the instrumentation code and the programmable logic to implement the instrumentation interface; and
wherein the instrumentation interface is configured to test a state of a signal from the circuitry of the DUT and interrupt the processor in response to the state of the signal satisfying a condition specified in a specification of the DUT.

9. The method of claim 8, wherein the instrumentation interface is configured to:
stop a clock signal to the circuitry of the DUT in response to the state of the signal satisfying the condition; and
start the clock signal to the circuitry of the DUT in response to the instrumentation code signaling to resume the clock signal.

10. The method of claim 1, wherein:
the SoC includes a plurality of processors, and the plurality of processors includes a first processor and a second processor;
generating the testbench executable code includes:
partitioning the testbench source code into a plurality of partitions, and the plurality of partitions includes a first partition and a second partition, and
compiling the first partition into first executable code, and compiling the second partition into second executable code; and
configuring the processor includes configuring the first processor to execute the first executable code and configuring the second processor to execute the second executable code.

11. A system comprising:
one or more computer processors configured to execute program code; and
a memory arrangement coupled to the one or more computer processors, wherein the memory arrangement is configured with instructions of a design tool that when executed by the one or more computer processors cause the one or more computer processors to perform operations including:
generating configuration data to implement circuitry for emulation of a design-under-test (DUT) on programmable logic of a system-on-chip (SoC);
generating testbench executable code from testbench source code, wherein the testbench executable code is configured to generate stimuli to the circuitry on the programmable logic; and
configuring a processor of the SoC to execute the testbench executable code and the programmable logic to implement the circuitry for emulation of the DUT.

12. The system of claim 11, wherein the memory arrangement is configured with instructions that when executed by the one or more computer processors cause the one or more computer processors to perform operations including:
generating instrumentation code to execute on the processor;
generating configuration data to implement an instrumentation interface as circuitry on the programmable logic; and
configuring the processor to execute the instrumentation code and the programmable logic to implement the instrumentation interface.

13. The system of claim 12, wherein the instructions for generating the instrumentation code include instructions for generating instrumentation code that communicates directly with the circuitry of the instrumentation interface.

14. The system of claim 12, wherein:
the instructions for generating the instrumentation code include instructions for generating instrumentation code that interfaces with an operating system; and
the instructions for configuring the processor include instructions for configuring the SoC to boot the operating system on the processor.

15. The system of claim 12, wherein:
the testbench source code includes SystemC code;
the instructions for generating the instrumentation code include instructions for generating instrumentation code that provides an interface to SystemC library functions for communicating the stimuli to the instrumentation interface through an operating system; and
the instructions for configuring the processor include instructions for configuring the SoC to boot the operating system on the processor and execute the SystemC library functions.

16. The system of claim 12, wherein:
the testbench source code includes hardware description language (HDL) code;
the instructions for generating the testbench executable code include instructions for generating code that interfaces with an HDL simulator;
the instructions for generating the instrumentation code include instructions for generating code that interfaces between the HDL simulator and an operating system; and
the instructions for configuring the processor include instructions for configuring the SoC to boot the operating system on the processor and execute the HDL simulator.

17. The system of claim 11, wherein the memory arrangement is configured with instructions that when executed by the one or more computer processors cause the one or more computer processors to perform operations including:
generating instrumentation code to execute on the processor;
generating configuration data to implement an instrumentation interface as circuitry on the programmable logic; and
configuring the processor to execute the instrumentation code and the programmable logic to implement the instrumentation interface; and
wherein the instrumentation interface is configured to test a state of a signal from the circuitry of the DUT and interrupt the processor in response to the state of the signal satisfying a condition specified in a specification of the DUT.

18. The system of claim 17, wherein the instrumentation interface is configured to:
stop a clock signal to the circuitry of the DUT in response to the state of the signal satisfying the condition; and
start the clock signal to the circuitry of the DUT in response to the instrumentation code signaling to resume the clock signal.

19. The system of claim 11, wherein:
the SoC includes a plurality of processors, and the plurality of processors includes a first processor and a second processor;
the instructions for generating the testbench executable code include instructions for:
partitioning the testbench source code into a plurality of partitions, and the plurality of partitions includes a first partition and a second partition, and
compiling the first partition into first executable code, and compiling the second partition into second executable code; and
the instructions for configuring the processor include instructions for configuring the first processor to execute the first executable code and configuring the second processor to execute the second executable code.

20. A system-on-chip (SoC), comprising:
programmable logic circuitry configured to emulate a design-under-test (DUT); and
a processor coupled to the programmable logic circuitry and configured to execute testbench executable code that generates stimuli to the DUT.
